(19) United States
(12) Patent Application Publication
(10) Pub. No.: US 2008/0036045 A1
(43) Pub. Date: Feb. 14, 2008

(54) PACKAGE-BASE STRUCTURE OF POWER SEMICONDUCTOR DEVICE AND MANUFACTURING PROCESS OF THE SAME

(75) Inventors: Chih-Ming Chen, Hsinchu (TW); Ching-Chi Cheng, Hsinchu (TW); An-Nong Wen, Hsinchu (TW)

Correspondence Address: KIRTON AND MCCONKIE, 60 EAST SOUTH TEMPLE,, SUITE 1800, SALT LAKE CITY, UT, 84111, US

(73) Assignee: SILICON BASE DEVELOPMENT INC., Hsinchu (TW)

(21) Appl. No.: 11/836,036

(22) Filed: Aug. 8, 2007

(30) Foreign Application Priority Data
Aug. 8, 2006 (TW) 095129113

(51) Int. Cl. H01L 31/036; H01L 21/44

(52) U.S. Cl. 257/627; 438/671; 257/E21.476; 257/E31.04

(57) ABSTRACT

A process of manufacturing a package base of a power semiconductor device includes the following steps. Firstly, a semiconductor substrate including a first surface and a second surface is provided. Then, a portion of the semiconductor substrate is patterned and removed to form a recess on the first surface of the semiconductor substrate, which serves as a receiving space for receiving a power semiconductor element therein. Then, a conducting layer is overlaid on the first surface including the receiving space. Afterward, a portion of the conducting layer is patterned and removed to form a conducting structure to be electrically connected to the power semiconductor device.

### FIELD OF THE INVENTION

The present invention relates to a package base, and more particularly to a package base of a power semiconductor device. The present invention also relates to a process of manufacturing a package base of a power semiconductor device.

### BACKGROUND OF THE INVENTION

Generally, trends in designing electronic apparatuses such as computers are miniaturization, weight reduction and portability enhancement as well as high performance. Accordingly, power semiconductor devices such as power metal oxide semiconductor field effect transistors or bipolar junction transistors (BJTs) have been highly developed recently and achieved a great deal of advances. Among these power semiconductor devices, power metal oxide semiconductor field effect transistors are the mainstream in the industry.

During operation of the electronic apparatus, the power metal oxide semiconductor field effect transistors may generate energy in the form of heat, which is readily accumulated and difficult to be dissipated away. Typically, two approaches are employed to package the power semiconductor devices. The first approach involves the use of a circuit board made of a composite material as a substrate. The power semiconductor devices are mounted on the circuit board and then encapsulated by a plastic molding operation. The second approach involves the use of a metallic frame as the substrate. The power semiconductor devices are mounted on the metallic frame and then encapsulated by an ejection molding operation or a plastic molding operation. These two approaches have some drawbacks. For example, since the temperature resistance and the heat-dissipating efficiency are not satisfactory, the packaged power semiconductor devices have low thermal conductivity. If the heat fails to be efficiently dissipated to the ambient, the elevated operating temperature might result in damage of the power semiconductor devices, reduced yield of the final products and/or reduced operation efficiency. For solving these problems, a ceramic molding process is implemented to reduce thermal resistance in order to increase heat-dissipating efficiency. In comparison with the packaging process of using the circuit board or the metallic frame, however, the ceramic molding process is not cost-effective.

### SUMMARY OF THE INVENTION

The present invention provides a package base for use in a power semiconductor device in order to enhance heat-dissipating efficiency and reduce the fabricating cost.

In accordance with an aspect of the present invention, there is provided a process of manufacturing a package base of a power semiconductor device. Firstly, a semiconductor substrate including a first surface and a second surface is provided. Then, a portion of the semiconductor substrate is patterned and removed to form a recess on the first surface of the semiconductor substrate, which serves as a receiving space for receiving a power semiconductor element therein. Then, a conducting layer is overlaid on the first surface including the receiving space. Afterward, a portion of the conducting layer is patterned and removed to form a conducting structure to be electrically connected to the power semiconductor device.

Preferably, the semiconductor substrate has a <100> lattice direction.

In an embodiment, the process further includes a step of forming a thermally conductive layer on the first surface or the second surface of the semiconductor substrate.

Preferably, the thermally conductive layer is made of a gold/tin (Au/Sn) alloy.

In an embodiment, the patterning and removing step of the semiconductor substrate include sub-steps of forming a mask layer on the first surface of the semiconductor substrate, forming a photoresist layer on the mask layer, using a photomask to define a photoresist pattern, etching the mask layer according to the photoresist pattern to form a first opening, removing a portion of the semiconductor substrate in the first opening to form the recess and removing the photoresist layer and the mask layer.

In an embodiment, second openings are formed in the etching step of the mask layer, from which portions of the semiconductor substrate are removed to form a plurality of through holes penetrating the first surface through the second surface.

In an embodiment, the conducting layer further covers inner walls of the through holes and the second surface around exits of the through holes.

In an embodiment, the portions of the semiconductor substrate in the first and second openings are removed by a dry-etching or wet-etching procedure.

In an embodiment, the portions of the semiconductor substrate in the first and second openings are removed by a laser drilling procedure.

In an embodiment, the further comprising a step of forming a silicon oxide insulating layer on the first surface of the semiconductor substrate including the receiving space, wherein the conducting layer is formed on the silicon oxide insulating layer.

Preferably, the conducting layer is made of a TiW/Cu/Ni/Au alloy, a Ti/Cu/Ni/Au alloy, a Ti/Au/Ni/Au alloy or an AlCu/Ni/Au alloy, and deposited on the silicon oxide insulating layer by a sputtering/electroplating procedure or an electroless plating procedure.

In an embodiment, the patterning and removing step of the conducting layer include sub-steps of forming a mask layer on the conducting layer, forming a photoresist layer on the mask layer, using a photomask to define a photoresist pattern, patterning the mask layer according to the photoresist pattern, etching the conducting layer with the patterned mask layer to form a first electrode structure area and a second electrode structure area in the conducting layer, removing the photoresist layer and the mask layer.

In an embodiment, the process is used for fabricating a package base of a power diode or a power metal oxide semiconductor transistor.

In accordance with another aspect of the present invention, there is provided a power semiconductor device. The power semiconductor device includes a power semiconductor element, a semiconductor substrate and a conducting structure. The semiconductor substrate has a recessed receiving space on a first surface thereof for receiving the power semiconductor element. The conducting structure is distributed on the first surface including the receiving space for electric connection to the power semiconductor element.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic cross-sectional view of a power semiconductor device according to a first embodiment of the present invention;

FIGS. 2A-2G are schematic cross-sectional views illustrating the steps of a process for fabricating the package base of the power semiconductor device of FIG. 1 according to the present invention;

FIG. 3 is a schematic top view of the power semiconductor device shown in FIG. 1;

FIG. 4 is a schematic cross-sectional view of a power semiconductor device according to a second embodiment of the present invention;

FIGS. 5A and 5B are respectively schematic cross-sectional and top views of a power semiconductor device according to a third embodiment of the present invention; and

FIGS. 6A and 6B are respectively schematic cross-sectional and top views of a power semiconductor device according to a fourth embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

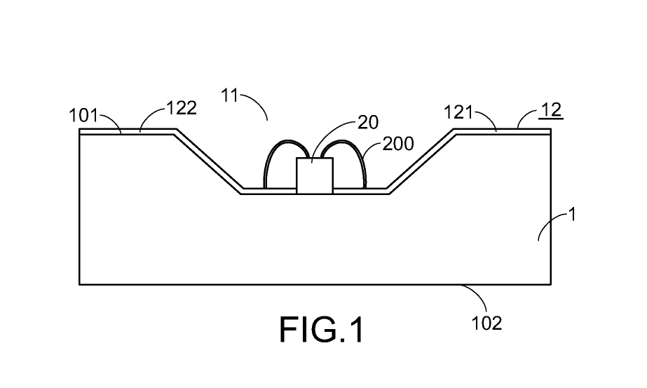

Referring to FIG. 1 a first embodiment of the present invention is illustrated. The power semiconductor part 20, for example, can be a power metal oxide semiconductor (power MOS) or a power diode. The package base comprises a substrate 1 including a first surface 101 and a second surface 102, a receiving space 11, a first conducting structure 121 and a second conducting structure 122. The substrate 1 is a silicon substrate with <100> lattice direction. The power semiconductor part 20 is accommodated within the receiving space 11. The first conducting structure 121 and the second conducting structure 122 are formed on the first surface 101. The power semiconductor part 20 is wire-bonded to the first conducting structure 121 and the second conducting structure 122 with conductive wires 200.

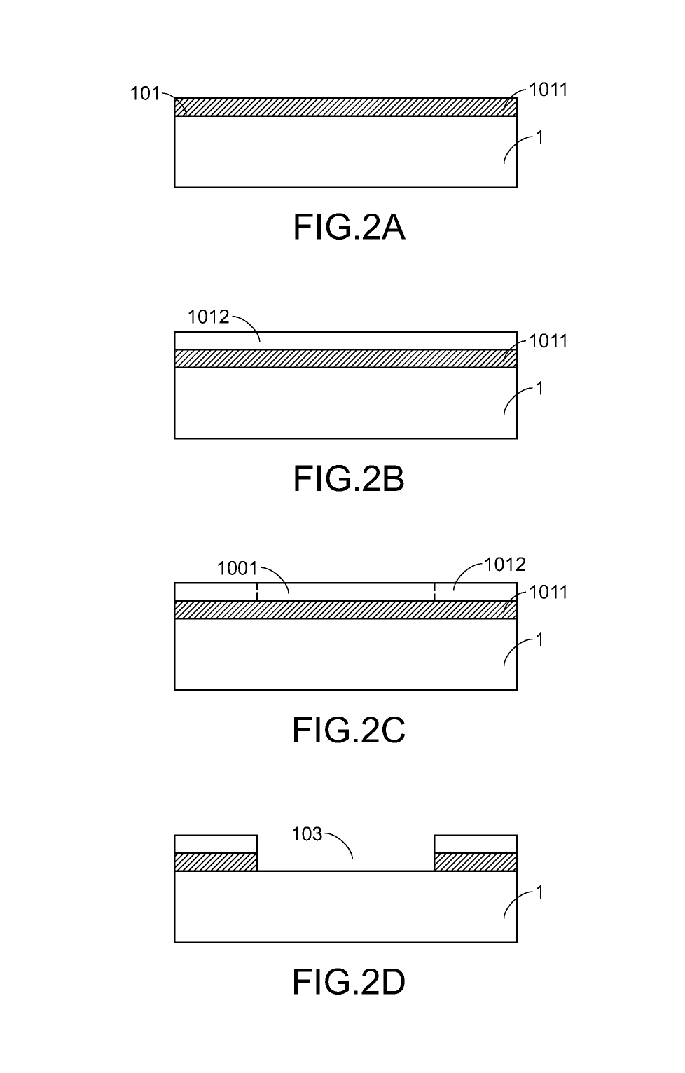

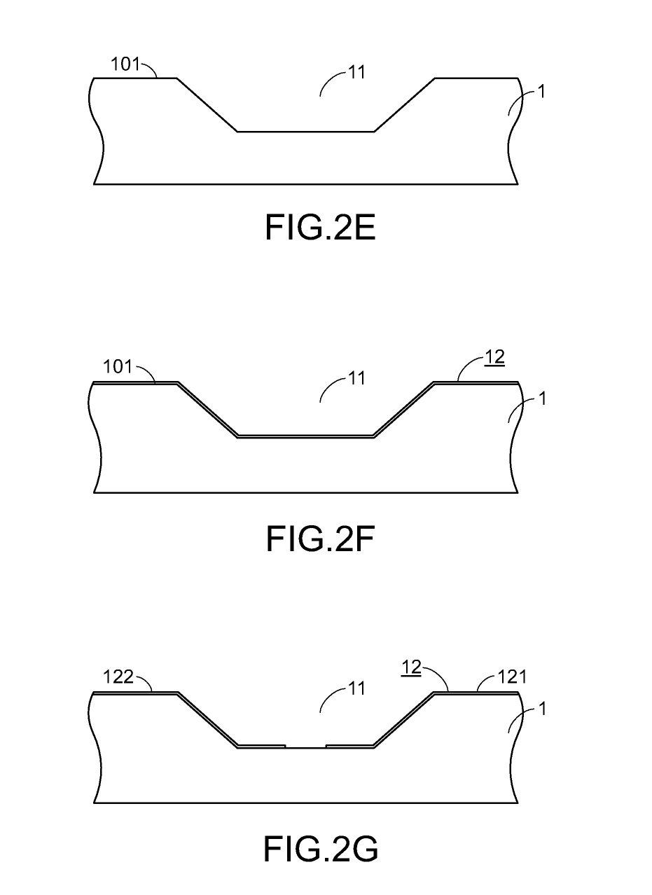

Hereinafter, a process for fabricating the package base of FIG. 1 is exemplified as follows with reference to FIGS. 2A-2G.

First of all, as shown in FIG. 2A, a mask layer 1011, which can be made of silicon nitride, silicon oxide or metallic material, is formed on the first surface 101 of the silicon substrate 1. Then, as shown in FIG. 2B, a photoresist layer 1012 is formed on the mask layer 1011, and as shown in FIG. 2C, a photoresist pattern 1001 is defined in the photoresist layer 1012 according to the pattern defined by a photomask (not shown). Next, as shown in FIG. 2D, the photoresist pattern 1001 is etched to form an opening 103. Then, as shown in FIG. 2E, an etching procedure is performed to partially etch off the silicon substrate 1 in the opening 13 and then remove the mask layer 1011 and the photoresist layer 1012, thereby defining the receiving space 11. Then, as shown in FIG. 2F, a conducting material is deposited on the first surface 101 of the silicon substrate 1 and the receiving space 11 as the conductive layer 12. For example, the conducting layer 12 is made of a TiW/Cu/Ni/Au alloy, a Ti/Cu/Ni/Au alloy, a Ti/Au/Ni/Au alloy or an AlCu/Ni/Au alloy. Afterwards, as shown in FIG. 2G, the conducting layer 12 is patterned and etched to define a first conducting structure 121 and a second conducting structure 122. After the coupling of the power semiconductor part 20 and wires 220, a power semiconductor device as shown in FIG. 1 is formed.

Alternatively, before the procedure of forming the conducting layer 12 as shown in FIG. 2F, a silicon oxide insulating layer (not shown) can be deposited on the first surface 101 of the silicon substrate 1 and the receiving space 11 by a sputtering/electroplating procedure or an electroless plating procedure. The insulating layer is advantageous of enhancing insulation between the first conducting structure 121, the second conducting structure 122 and the silicon substrate 1.

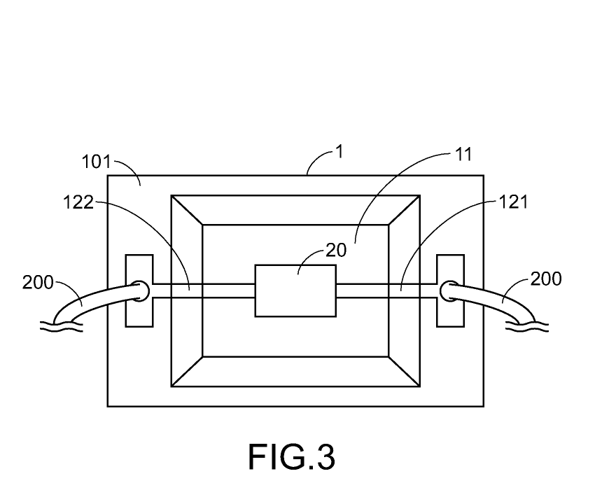

Referring to FIG. 3, a schematic front view of the power semiconductor device shown in FIG. 1 is illustrated. The first conducting structure 121 and the second conducting structure 122 serving as a positive electrode area and a negative electrode area, respectively, are formed by performing a masking and etching process to remove portions of the conductive layer 12. Afterwards, the power semiconductor element 20 is wire-bonded to the first conducting structure 121 and the second conducting structure 122.

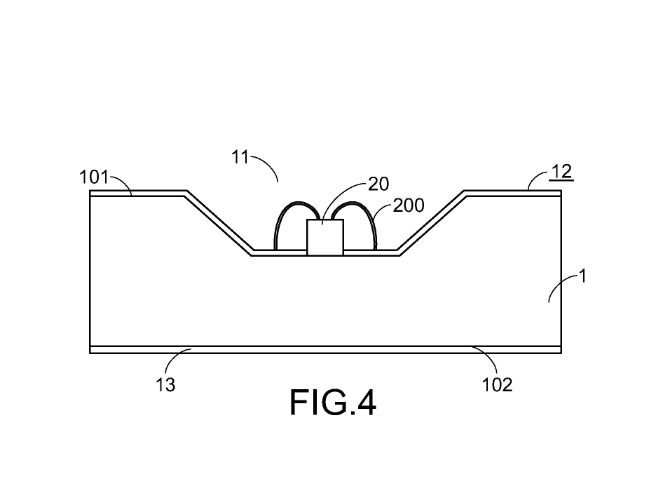

Generally, a lot of heat is generated during the operation of the power semiconductor device, and dissipated outside the device from the bottom of the substrate. For enhancing heat-dissipating efficiency, another embodiment of the package base further includes a thermally conductive layer 13 formed onto the second surface 102 of the silicon substrate 1, as shown in FIG. 4. The thermally conductive layer 13 is made of, for example, a gold/tin (Au/Sn) alloy consisting of 80% Au and 20% Sn. In addition to enhancing heat-dissipating efficiency, the thermally conductive layer 13 also serves as a bonding metal for facilitating adhesion of the silicon substrate 1 to a circuit board (not shown).

As the package base according to the present invention is produced by performing a semiconductor manufacturing process, the process cost and material cost of the present process is lower than conventional processes for fabricating circuit-board type package bases and metallic-frame type package bases,. Furthermore, since the heat generated due to the operation of the power semiconductor device is readily conducted to the first conducting structure 121, the second conducting structure 122 and the thermally conductive layer 13, the heat-dissipating efficiency of the package base is enhanced.

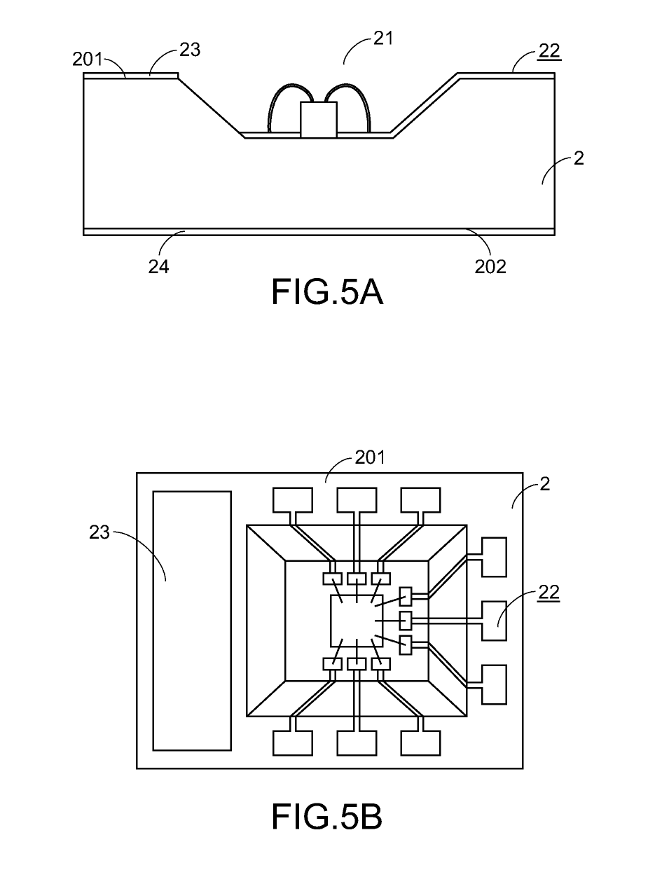

Referring to FIG. 5A and FIG. 5B, schematic cross-sectional and top views of a power semiconductor device according to another embodiment of the present invention are respectively illustrated. The package base in this embodiment comprises a silicon substrate 2 having a first surface 201 and a second surface 202, a receiving space 21, plural conducting structures 22 and a thermally conductive layer 23. Unlike the embodiment of package base shown in FIG. 4, the silicon substrate 2 in this embodiment is bonded to a circuit board (not shown) with the first surface 201 instead of the second surface 202. Therefore, the thermally conductive layer 23 is formed on the first surface 201 of the silicon substrate 2 for bonding to the circuit board. Consequently, the package base is flip-bonded to the circuit board. For good alignment of the conducting structures 22 with the circuitry on the circuit board and assure of normal electric connection, a calibration marker 24 associated with the conducting structures 22 is formed on the second surface 202 of the silicon substrate 2. When the silicon substrate 2 is flip-bonded onto the circuit board, the calibration marker 24 can be referred to locate the conducting structures 22 so as to facilitate the electric connection between the conducting structures 22 and the circuit board. Since the thermally conductive layer 23 and the conducting structures 22 are formed on the first surface 201 of the silicon substrate 2, the process of fabricating the package base is simplified.

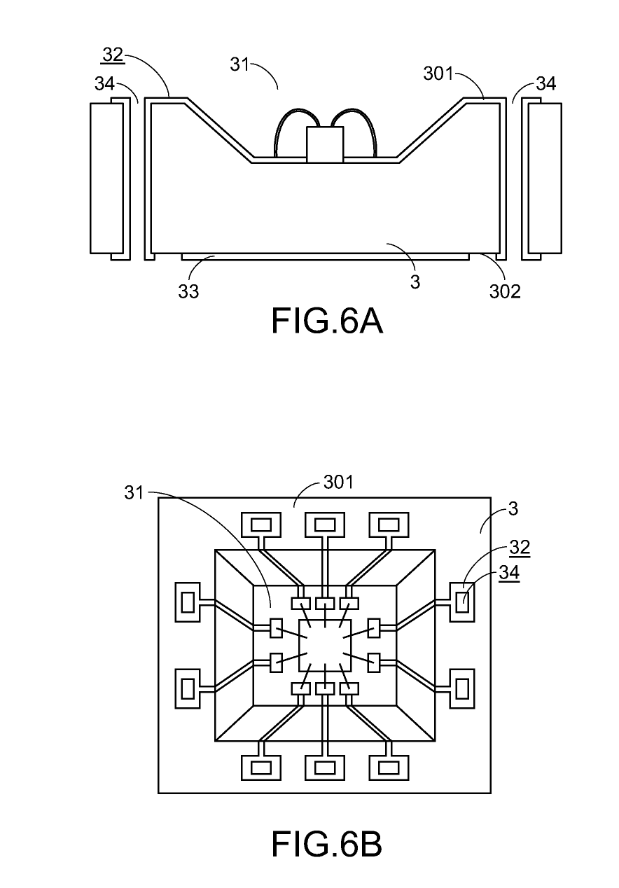

Referring to FIG. 6A and FIG. 6B, schematic cross-sectional and top views of a power semiconductor device according to a further embodiment of the present invention are respectively illustrated. The package base in this embodiment comprises a silicon substrate 3 having a first surface 301 and a second surface 302, a receiving space 31, plural conducting structures 32 and a thermally conductive layer 33 formed on the second surface 302 of the silicon substrate 3. The second surface 302 of the silicon substrate 3 of the package base is bonded to a circuit board (not shown) via the thermally conductive layer 33. In addition, the package base in this embodiment further includes plural through holes 34 in the silicon substrate 3. These through holes 34 are formed by an etching procedure (e.g. a wet-etching or dry-etching procedure) or a laser drilling procedure along with the formation of an opening (not shown here, see opening 103 in FIG. 2D) for defining the receiving space 31. These through holes 34 extend from the first surface 301 to the second surface 302 of the silicon substrate 3. The conducting structures 32 are formed on the first surface 301 and the inner walls of the through holes 34 while partially covering the second surface 302 around the exits of the through holes 34 for electronic connection to the circuit board coupled to the second surface 302.

In the above embodiments, the etching procedure can be a wet-etching procedure or a dry-etching procedure. On the other hand, a laser drilling procedure can be performed to drill holes in the silicon substrate.

It is understood from the above description that due to the implementation of the semiconductor manufacturing process and proper disposition of the conducting layer, the process for manufacturing a package base according to the present invention is cost-effective and the package base according to the present invention is highly heat-dissipative in comparison with the conventional circuit-board type package bases and the metallic-frame type package bases.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process of manufacturing a package base of a power semiconductor device, comprising:
providing a semiconductor substrate including a first surface and a second surface;
patterning and removing a portion of the semiconductor substrate to form a recess on the first surface of the semiconductor substrate, which serves as a receiving space for receiving a power semiconductor element therein;
overlying a conducting layer on the first surface including the receiving space; and
patterning and removing a portion of the conducting layer to form a conducting structure to be electrically connected to the power semiconductor device.

2. The process according to claim 1 wherein the semiconductor substrate has a <100> lattice direction.

3. The process according to claim 1 further including a step of forming a thermally conductive layer on the first surface or the second surface of the semiconductor substrate.

4. The process according to claim 3 wherein the thermally conductive layer is made of a gold/tin (Au/Sn) alloy.

5. The process according to claim 1 wherein the patterning and removing step of the semiconductor substrate include sub-steps of:
forming a mask layer on the first surface of the semiconductor substrate;
forming a photoresist layer on the mask layer;
using a photomask to define a photoresist pattern;
etching the mask layer according to the photoresist pattern to form a first opening;
removing a portion of the semiconductor substrate in the first opening to form the recess; and
removing the photoresist layer and the mask layer.

6. The process according to claim 5 wherein second openings are formed in the etching step of the mask layer, from which portions of the semiconductor substrate are removed to form a plurality of through holes penetrating the first surface through the second surface.

7. The process according to claim 6 wherein the conducting layer further covers inner walls of the through holes and the second surface around exits of the through holes.

8. The process according to claim 6 wherein the portions of the semiconductor substrate in the first and second openings are removed by a dry-etching or wet-etching procedure.

9. The process according to claim 6 wherein the portions of the semiconductor substrate in the first and second openings are removed by a laser drilling procedure.

10. The process according to claim 1 further comprising a step of:
forming a silicon oxide insulating layer on the first surface of the semiconductor substrate including the receiving space;
wherein the conducting layer is formed on the silicon oxide insulating layer.

11. The process according to claim 10 wherein the conducting layer is made of a TiW/Cu/Ni/Au alloy, a Ti/Cu/Ni/Au alloy, a Ti/Au/Ni/Au alloy or an AlCu/Ni/Au alloy, and deposited on the silicon oxide insulating layer by a sputtering/electroplating procedure or an electroless plating procedure.

12. The process according to claim 1 wherein the patterning and removing step of the conducting layer include sub-steps of:
forming a mask layer on the conducting layer;
forming a photoresist layer on the mask layer;
using a photomask to define a photoresist pattern;
patterning the mask layer according to the photoresist pattern;
etching the conducting layer with the patterned mask layer to form a first electrode structure area and a second electrode structure area in the conducting layer; and
removing the photoresist layer and the mask layer.

13. The process according to claim 1 for fabricating a package base of a power diode or a power metal oxide semiconductor transistor.

14. A power semiconductor device, comprising:
a power semiconductor element;
a semiconductor substrate having a recessed receiving space on a first surface thereof for receiving the power semiconductor element; and
a conducting structure distributed on the first surface including the receiving space for electric connection to the power semiconductor element.

15. The package base according to claim 14 wherein the semiconductor substrate has a <100> lattice direction.

16. The power semiconductor device according to claim 14 further comprising a thermally conductive layer on the first surface or the second surface of the semiconductor substrate for dissipating heat and bonding the power semiconductor device to a circuit board.

17. The power semiconductor device according to claim 16 wherein the thermally conductive layer is made of a gold/tin (Au/Sn) alloy.

18. The power semiconductor device according to claim 16 further comprising a calibration marker formed on the second surface of the semiconductor substrate for locating the conducting structure when the thermally conductive layer is formed on the first surface to have the power semiconductor device is flip-bonded to the circuit board.

19. The power semiconductor device according to claim 14 further comprising at least two through holes extending from the first surface to the second surface of the semiconductor substrate, wherein the conducting structure is further distributed on the inner walls of the through holes.

20. The power semiconductor device according to claim 14 wherein the conducting structure is made of a TiW/Cu/Ni/Au alloy, a Ti/Cu/Ni/Au alloy, a Ti/Au/Ni/Au alloy or an AlCu/Ni/Au alloy.
